(19) United States
(12) Patent Application Publication
(10) Pub. No.: US 2016/0285450 A1
(43) Pub. Date: Sep. 29, 2016

(54) Sensor Device and Method for the Detection of a Gripping of a Hand-Held Device as Well as a Hand-Held Device

(71) Applicant: Walli Fasshauer, Neubiberg (DE)

(72) Inventors: Holger Steffens, Munchen (DE); Peter Fasshauer, Neubiberg (DE); Claus Kaltner, Bergkirchen (DE)

(21) Appl. No.: 13/808,700

(22) PCT Filed: Jun. 29, 2011
(86) PCT No.: PCT/EP11/60968

§ 371 Date: Apr. 6, 2016

(30) Foreign Application Priority Data
Jul. 5, 2010 (DE) 10 2010 030 959.1

(51) Int. Cl. H03K 17/96; G06F 1/32; G01N 27/22

(52) U.S. Cl. CPC H03K 17/9622; G01N 27/228; G06F 1/3231; G06F 3/03543

(57) ABSTRACT

A sensor device for the detection of a gripping of a hand-held device with one hand has at least one first electrode and at least one second electrode. The first electrode can be operated in a first operating mode. The second electrode can be operated in the first operating mode and in a second operating mode. In the first operating mode, the capacitive coupling between the first electrode and the second electrode is analyzed. In the second operating mode, a capacitive load of the second electrode is analyzed against a reference ground.

### CROSS-REFERENCE TO RELATED APPLICATIONS

This application is a U.S. National Stage Application of International Application No. PCT/EP2011/060968 filed Jun. 29, 2011, which designates the United States of America, and claims priority to German Application No. 10 2010 030 959.1 filed Jul. 5, 2010, the contents of which are hereby incorporated by reference in their entirety.

### TECHNICAL FIELD

The present invention relates to a sensor device for the detection of a gripping of a hand-held device with one hand. Furthermore, the invention relates to a method for the detection of a gripping of a hand-held device with one hand, wherein the hand-held device comprises a sensor device according to the present invention for the detection of the gripping. Furthermore, the invention relates to a hand-held device comprising a sensor device according to the present invention.

### BACKGROUND

It has long been desired to reliably detect a gripping of the hand-held device with one hand, particularly with regard to electrical hand-held devices. For reliably detecting a gripping of a hand-held device with one hand, the hand-held device, such as a cell phone, can be provided with additional functions being performed depending on whether the hand-held device is gripped with one hand. For example, a cell phone can be turned on and/or the key lock can be unlocked when it is gripped with one hand. When letting go of the cell phone, it can be turned off and/or the key lock can be activated.

A sensor device which can detect the approximation or touch of a hand-held device with one hand is known from GB 2 398 138 A. The sensor device comprises a capacitive sensor, which sets the hand-held device, such as a computer mouse, to an active mode in case of approximation or touch and automatically sets the computer mouse to a sleep mode when taking the hand off the computer mouse.

The capacity of the capacitive sensor changing with the approximation is measured for the detection of the approximation to the computer mouse, wherein a predetermined capacity represents the switching threshold for a wake-up detector.

Tests have shown that the wake-up detector mentioned in GB 2 398 138 A has the disadvantage that it does not reliably detect an approximation of a hand to the wake-up detector. In the most unfavorable case, the approximation of a hand to the wake-up detector is even wrongly detected. This is particularly the case when the change of the capacity of the capacitive sensor in case of a hand approximating to the sensor is only very low.

### SUMMARY

Accoridng to various embodiments, solutions can be provided in order to at least partially avoid the disadvantages known from the state of the art and to achieve a precise and secure detection of a gripping of a hand-held device, particularly of an electrical hand-held device.

According to various embodiments, a sensor device may comprise at least one first electrode and at least one second electrode being coupled with an analysis device, wherein the at least one first electrode can be operated in a first operating mode, the at least one second electrode can be operated in said first operating mode and in a second operating mode, in the first operating mode, the capacitive coupling between the at least one first electrode and the at least one second electrode are analyzed by the analysis device, and in the second operating mode, a capacitive load of the at least one second electrode against a reference ground are analyzed by the analysis device

### BRIEF DESCRIPTION OF THE DRAWINGS

Further details and features as well as further advantages can be found in the following description in combination with the drawings as follows:

FIG. 1 a cell phone comprising a sensor device known from the state of the art for the approximation detection;

FIG. 2 a sensor device according to the various embodiments with two sensor electrodes being operated in a first operating mode (transmission mode);

FIG. 3 a sensor device according to various embodiments with two sensor electrodes being operated in a second operating mode (loading mode), respectively;

FIG. 4 a sensor device according to various embodiments with two sensor electrodes being operated in a first operating mode as well as in a second operating mode;

FIG. 5 the course of two sensor signals over time and depending on whether the electrical hand-held device is earthed or not, wherein a first sensor signal is assigned to the first operating mode and a second sensor signal is assigned to the second operating mode;

FIG. 6 an example of implementation of a sensor device, which can be operated in a first operating mode as well as in a second operating mode;

FIG. 7 the sensor device according to FIG. 6, furthermore comprising a compensating electrode; and

FIG. 8 the sensor device according to FIG. 6, furthermore comprising two compensating electrodes.

### DETAILED DESCRIPTION

According to various embodiments, a sensor device may comprise at least one first electrode and at least one second electrode being coupled with an analysis device is provided. The at least one first electrode can be operated in a first operating mode. The at least one second electrode can be operated in the first operating mode and in a second operating mode. In the first operating mode, the capacitive coupling between the at least one first electrode and the at least one second electrode can be analyzed by the analysis device. In the second operating mode, a capacitive load of the at least one second electrode against a reference ground can be analyzed by the analysis device.

The at least one first electrode can be operated in the second operating mode. Thus, a gripping of a hand-held device can also be detected in the second operating mode.

It is advantageous if an alternating electrical signal can be applied to the second electrode in the first operating mode and in the second operating mode, wherein the capacitive coupling between the first electrode and the second electrode is represented by the electric current flowing in the first electrode.

An alternating electrical signal can be applied to the first electrode in the second operating mode, wherein a capacitive load of the at least one first electrode against a reference ground can be analyzed by the analysis device.

The analysis device can be configured to provide a sensor signal in each of the first operating mode and the second operating mode, which is indicative for the capacitive coupling between the first electrode and the second electrode or for the capacitive load of the first electrode and/or the second electrode, respectively.

The sensor device can be operated sequentially in the first operating mode and in the second operating mode.

The sensor device can be operated in parallel in the first operating mode and in the second operating mode.

The capacitive load to be analyzed in the second operating mode can be used as reference value for adjusting a sensitivity of the sensor device in the first operating mode.

It has proven advantageous when the sensor device comprises a third electrode, wherein an alternating electrical signal can be applied to the third electrode, having a phase and/or amplitude differing from the phase and/or the amplitude of the alternating electrical signal applied to the second electrode.

The sensor device can also comprise a third electrode and a fourth electrode, which can each have an alternating electrical signal applied to them. It is advantageous when the sensor device can be operated in a third operating mode, wherein the capacitive couplings between the first electrode and the third electrode and between the second electrode and the fourth electrode can be analyzed by the analysis device.

Furthermore, a hand-held device is provided, comprising at least a sensor device according to various embodiments.

The first electrode and the second electrode are preferentially arranged relative to one another on the hand-held device in such a way that they are at least partially overlapped with one hand when gripping the hand-held device with one hand.

The first electrode and the second electrode can be arranged at two walls facing each other, preferably at two side walls of a housing of the hand-held device facing each other.

Furthermore, according to other embodiments, a method for the detection of a gripping of a hand-held device with a first electrode and a second electrode, particularly with a sensor device according to the present invention, with one hand, may comprise at least the following steps:
applying an alternating electrical signal to the second electrode, so that it emits an alternating electrical field,
in a first operating mode, measuring the capacitive coupling between the first electrode and the second electrode and providing a first measuring signal,
in a second operating mode, measuring the capacitive load of the second electrode against a reference ground and providing a second measuring signal,
   wherein the measuring signals are indicative for the gripping of the hand-held device with the hand.

The measuring steps can be performed in parallel or sequentially.

The second measuring signal can be used to adjust the sensitivity of the sensor device in the first operating mode.

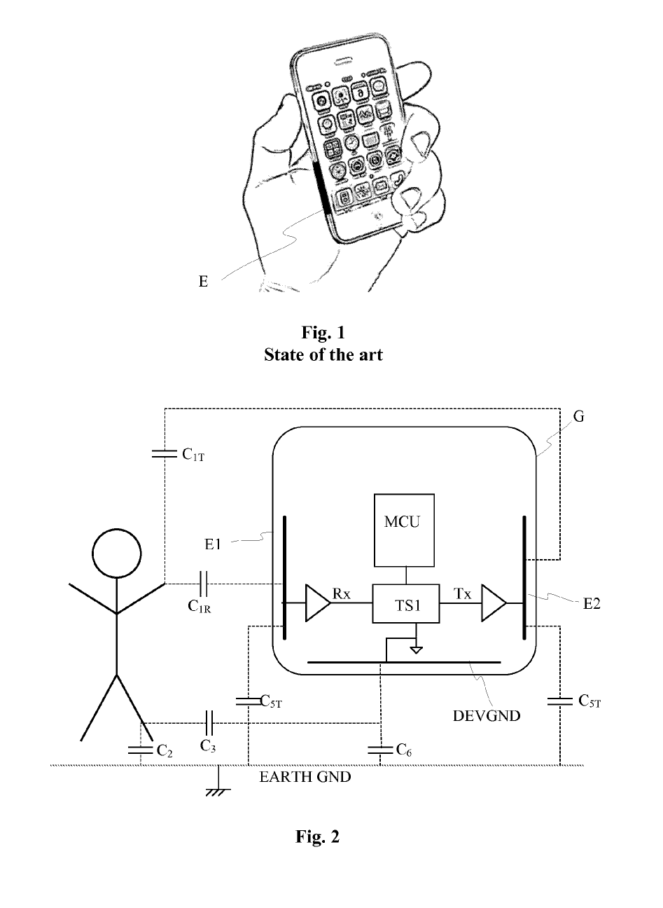

FIG. 1 shows a cell phone comprising an approximation sensor known from the state of the art. Such an approximation sensor is, for example, known from the GB 2 398 138 A mentioned above. An electrode E of the approximation sensor is arranged at the left housing wall of the cell phone. When a hand approximates to the cell phone or to the electrode E, the capacity at the electrode E changes. This capacity change can be analyzed by an analysis device coupled with the electrode E. However, it is disadvantageous that particularly in case of battery-operated devices and in case of very low capacitive couplings between the hand of the user and the electrode E, the changes of the coupling capacity are also very small when the hand approximates to the electrode E, which could mean that an approximation is possibly not detected reliably.

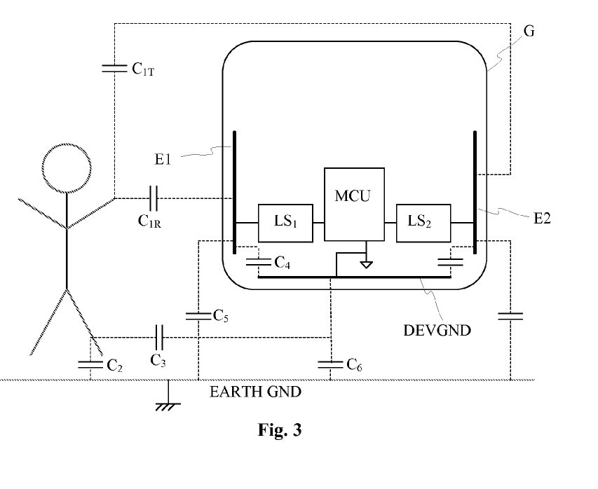

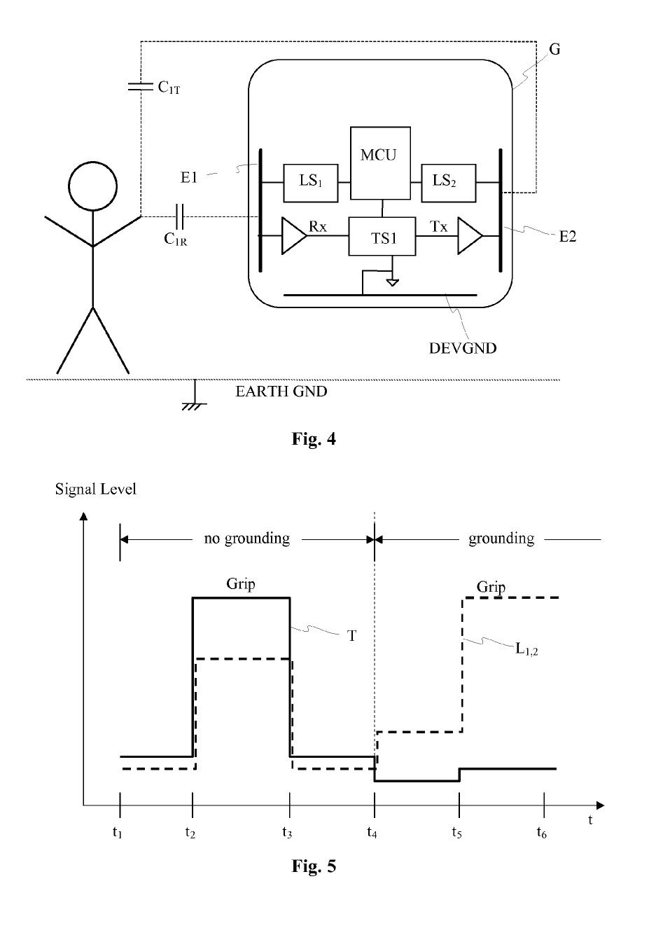

Various embodiments are described in more detail below with reference to FIG. 2 to FIG. 8. Accordingly, the sensor device is operated in a first operating mode and in a second operating mode. This enables a particularly reliable and precise detection of a gripping of a hand-held device with one hand. To begin with, the operation of the sensor device in a first operating mode is described with reference to FIG. 2 for further clarification of the sensor device according to various embodiments. The sensor device according to various embodiments is then described in a second operating mode with reference to FIG. 3. The sensor device according to various embodiments can be operated in the first operating mode as well as in the second operating mode is then described with reference to FIG. 4. The following FIG. 5 to FIG. 8 show further details for the implementation of a sensor device according to various embodiments.

FIG. 2 shows the sensor device according to various embodiments being operated in a first operating mode. The first operating mode is hereinafter referred to as “transmission mode”.

For the operation of the sensor device in the transmission mode, the sensor device comprises a sensor circuit TSI and two electrodes E1 and E2 being coupled with the sensor circuit TSI. In the transmission mode, the electrode E2 is used as transmitting electrode and the electrode E1 is used as receiving electrode. The capacitive coupling between the two electrodes E1 and E2 is analyzed in the transmission mode.

For the operation of the sensor device in the transmission mode, an alternating electrical signal is applied to the electrode E2, so that it emits an alternating electrical field. When a hand approximates to the electrodes E1 and E2, the alternating electrical field emitted at the electrode E2 is coupled into the electrode E1 via the hand, so that a capacitive coupling is created between the electrode E2 and the electrode E1. In a further embodiment not shown here, such a (low) capacitive coupling can be created even if no hand approximates to the sensor device. However, the electrodes E1 and E2 are preferentially arranged relative to one another in such a way that if no hand approximates, no capacitive coupling is created between the electrodes E1 and E2.

The capacitive coupling between the two electrodes E1 and E2 changes with further approximation of the hand to the sensor device, so that a change of the coupling capacity between the electrodes E1 and E2 can be used as indicator for the approximation of a hand to the sensor device.

The equivalent circuit diagram according to FIG. 2 only considers the capacities substantial for the operation of the sensor device in the transmission mode. The operation of the sensor device according to various embodiments in the transmission mode is particularly suitable for battery-operated devices, since in most cases there is no or only a very low coupling of the user to the ground of the device DEVGND and virtually no coupling of the device itself to ground.

However, if there is a capacitive coupling of the user to the ground of the device or of the device to ground or if this capacitive coupling becomes significant, the receiving signal at the electrode E1, i.e. the alternating electrical field coupled into the electrode E1, is considerably attenuated. A significant increase of the coupling of the device to ground can, for example, be created by connecting additional devices. This is the case, for example, with cell phones when they are connected with a charging device. The precision of the approximation detection or the detection of the gripping of a hand-held device with one hand can be reduced in the transmission mode by means of a significant coupling to ground.

FIG. 3 shows a sensor device according to various embodiments being operated in a second operating mode. The second operating mode is hereinafter referred to as “loading mode”. When the sensor device according to various embodiments is operated in the loading mode, a capacitive load between an electrode and a reference ground is used for detecting the approximation of a hand to the electrode.

A capacitive load means that the strength of an active electric field from the electrode to the reference ground is increased by the approximation of the electrically conductive hand and thus leads to an increase of the capacity between the electrode and the reference ground. The capacitive load is a measure of the strength of an active electric field from the electrode to the reference ground or a measure of the capacity between electrode and reference ground.

Thus, the capacity of the electrode is analyzed against a reference ground. It is characteristic of the loading mode that a transmitter and a receiver are connected to the same electrode.

The sensor device shown in FIG. 3 comprises two sensors, each being operated in the second operating mode, i.e. in the loading mode. The first sensor comprises a first sensor circuit LS1 and a sensor electrode E1 coupled with it. The second sensor comprises a second sensor circuit LS2 and a second sensor electrode E2 coupled with it. The two sensor circuits LS1, LS2 are each coupled with a microcontroller MCU, which preferentially processes or analyzes the sensor signals provided by the two sensor circuits LS1, LS2 and preferentially transmits unique sensor information to a master processing unit of an electrical device, such as a cell phone.

The operation of the sensor device according to various embodiments in the loading mode is described with reference to the first sensor LS1, E1 as follows.

For the operation of the sensor LS1, E1, an alternating electrical signal is generated being applied to the sensor electrode E1. The generation of this alternating electrical signal can be performed by means known from the state of the art, such as a signal generator. Applying an alternating electrical signal to the sensor electrode E1 results in an alternating electrical field being emitted by the sensor electrode E1. When a hand approximates to the sensor electrode E1, the capacity between the sensor electrode E1 and the approximating hand increases, resulting in an increasing capacitive load of the electrode against the reference ground. The capacitive load is measured at the sensor circuit LS1. For example, the change of the capacitive load can be determined by the change of the load current via a shunt resistor.

When a hand approximates to the left side of the cell phone G or when the user touches the left side of the cell phone G, this increases the capacitive coupling between the user and the left electrode E1. The capacitive coupling between the electrode E1 and the user is indicated in FIG. 3 as concentrated capacity C_{1R}. A return current path can be created by a direct coupling of the user to the ground DEVGND of the cell phone G as well as by a coupling of the user to other conductive objects and to ground and the coupling back to the ground of the device DEVGND. The coupling of the user to the ground of the device is indicated as capacity C₃ in FIG. 3. The coupling of the user to other conductive objects and to ground is indicated as capacity C₂ and the coupling back to the ground of the device is indicated as capacity C₆ in FIG. 3.

A further capacitive load of the electrode E1 may also occur due to the coupling of the electrode E1 to ground, since it is in series with the capacity C₆. The capacity between the electrode E1 and ground is indicated as capacity Cs in FIG. 3.

The capacities C₂ to C₆ are variables which may keep changing permanently. The change can be subject to the position, the way the person holds its hand etc. It has become evident that an additional load of the electrode E1 in case of the approximation of a hand to the electrode E1 or in case of a gripping the electrode E1 with the hand, the coupling capacity C_{1R} is the capacity mainly dominating for the signal change in the sensor LS1, since it is in series with the remaining load capacities C₂ to C₆ and it is low compared to them. This also means that the signal changes of the sensor device being operated in the loading mode remain substantially independent of different grounding situations.

By providing two sensors LS1, E1 or LS2, E2, each being operated in the loading mode, it advantageously possible to detect a gripping of the cell phone G. As a prerequisite for a reliable detection, the sensor electrode E1 and the sensor electrode E2 must be each arranged at the cell phone G in such a way that they are preferentially only covered by the hand when gripping the cell phone G. For example, the sensor electrode E1 can be arranged at the left side wall of a housing of the cell phone, the sensor electrode E2 can be arranged at the right housing wall of the cell phone G. As a matter of course, the electrodes E1 and E2 can also be arranged at different places on the cell phone housing, depending on the desired application.

However, for the detection of only the approximation of a hand to the cell phone, it is sufficient to provide only one of the two sensors, LS1, E1 or LS2, E2.

In order to ensure a more precise detection of the approximation or of a gripping of a hand-held device with one hand largely independent of the coupling to ground, the sensor device according to various embodiments is operated in the first operating mode, i.e. in the transmission mode, as well as in the second operating mode, i.e. in the loading mode. A sensor device being operated in the first operating mode and in the second operating mode is described below in more detail with reference to FIG. 4.

FIG. 4 shows a sensor device according to various embodiments with two sensors, LS1, E1 and LS2, E2, being intended for the operation of the sensor device in the loading mode, and a sensor TS1, E1, E2, being intended for the operation of the sensor device in the transmission mode. The functioning of the sensor device according to various embodiments in the loading mode has been described with reference to FIG. 3. The functioning of the sensor device in the transmission mode has been described with reference to FIG. 2.

As can be seen from FIG. 4, the electrodes E1 and E2 are used for the operation of the sensor device in the loading mode as well as for the operation of the sensor device in the transmission mode. As a matter of course, it is also possible to provide individual electrodes for each of the two operation modes. In addition to that, the sensor device according to various embodiments can be operated in both operation modes when doing without one of the two sensor circuits LS1 or LS2 shown in FIG. 4.

For the functional description of the sensor device according to various embodiments, which can be operated in both the operation modes, FIG. 4 only shows the active coupling capacity C_{1T} on the electrode E2 (transmitting electrode) and the active coupling capacity C_{1R} on the electrode E1 (receiving electrode). In case of an approximation or a gripping of the hand-held device with one hand, sensor signals are generated by the respective sensor circuits TS1 or LS1, LS2 in the transmission mode as well as in the loading mode. The sensor signals generated by the respective sensor circuits TS1, LS1 and LS2 may differ according to the embodiments of FIG. 2 and FIG. 3, depending on the coupling situation, particularly the coupling to ground.

FIG. 5 shows a typical course of a sensor signal being provided by a sensor operated in the transmission mode and of a sensor signal being provided by a sensor operated in the loading mode over time. The temporal variation of the levels of the two sensor signals is shown for several load scenarios at different points in time. The signal T corresponds to the sensor signal of the sensor device in the transmission mode, the sensor signals L1, L2 correspond to the sensor signals of the sensor device in the loading mode. For a better illustration of the temporal variations of both signals, the sensor signal T is shown slightly offset with regard to the sensor signals L1, L2. In a specific case, the level changes of the sensor signal T and the sensor signals L1, L2 can also take place simultaneously.

The capacitive sensor device is not grounded between the points in time t1 and t4. These signal courses are plotted for a grounded sensor device between the points in time t4 and t6.

The sensor device according to various embodiments is considered in the unloaded state of rest, i.e. without approximation of a hand to the sensor device or without gripping of a hand-held device with a sensor device with one hand, and in the ungrounded state between the points in time t1 and t2.

Between the points in time t2 and t3, there is an approximation of a hand to the sensor device or a gripping of a hand-held device with a sensor device with one hand without relevant coupling to ground. In this case, the sensor device in the transmission mode as well as the sensor device in the loading mode show a clear increase of the respective sensor signals T, L1, L2, wherein the two sensor subsystems LS1, LS2 provide almost identical sensor signals L1 and L2 in the loading mode.

At the point in time t3, the hand departs from the sensor device or the hand-held device is let go of. The levels again drop down to the initial values at the point in time t1.

At the point in time t4, a grounding of the hand-held device takes place, such as by connecting a charging device to the hand-held device. In this case, the signal being transmitted between the electrode E2 and the electrode E1 in the transmission mode is attenuated considerably due to the occurring coupling to ground described with reference to FIG. 2, so that a gripping of the hand-held device at the point in time t5 only results in a small change of level of the signal T. In contrast to this, the sensor signals L1, L2 significantly increase in the sensor circuits LS1, LS2 in the loading mode, since the grounding results in a higher capacitive load at the respective electrodes E1 and E2 (cf. FIG. 3).

Since the electrical hand-held devices, particularly the battery-operated devices, are mainly operated without relevant coupling to ground, the sensor signal T of the sensor device in the transmission mode is preferentially used for detecting an approximation to a hand-held device or a gripping of a hand-held device with one hand.

The sensor signals L1, L2 of the sensor device according to various embodiments in the loading mode are preferentially used as reference signals for detecting a possible grounding situation. In case there is no grounding, the sensor signals L1, L2 can be used as redundant information on the sensor signal T, in order to ensure an increase of the detection reliability. In case of the grounding, the sensor signals L1, L2 in combination with the sensor signal T represent a recognition criterion for the grounding, so that the sensor device according to various embodiments can be switched to a higher sensitivity in the transmission mode.

The correlation of the sensor signals can be effected, for example, by a ratio L1/T or L2/T or also (L1+L2)/T of the sensor signals L1, L2 and the sensor signal T. In the ungrounded case, this ratio remains nearly constant, whereas it significantly increases in the grounded case due to the levels shown in FIG. 5 and thus provides information on the grounding state.

This way, the sensor device can be adjusted in the transmission mode. For example, the amplitude of the alternating signal applied to the electrode E2 can be scaled up or down, depending on the capacitive load of the electrodes in the loading mode. As an alternative or in addition to that, the threshold values for an approximation or touch detection in the transmission mode can be adjusted, depending on the sensor signals L1 and/or L2.

The combination of the sensor signals L1, L2 with the sensor signal T thus provides increased detection reliability in numerous application scenarios.

A sensor device according to various embodiments shown in FIG. 4 provides an approximation of a user to a hand-held device or a gripping of a hand-held device with one hand with a low error rate with regard to detection and rejection as well as substantially independent of the coupling to ground.

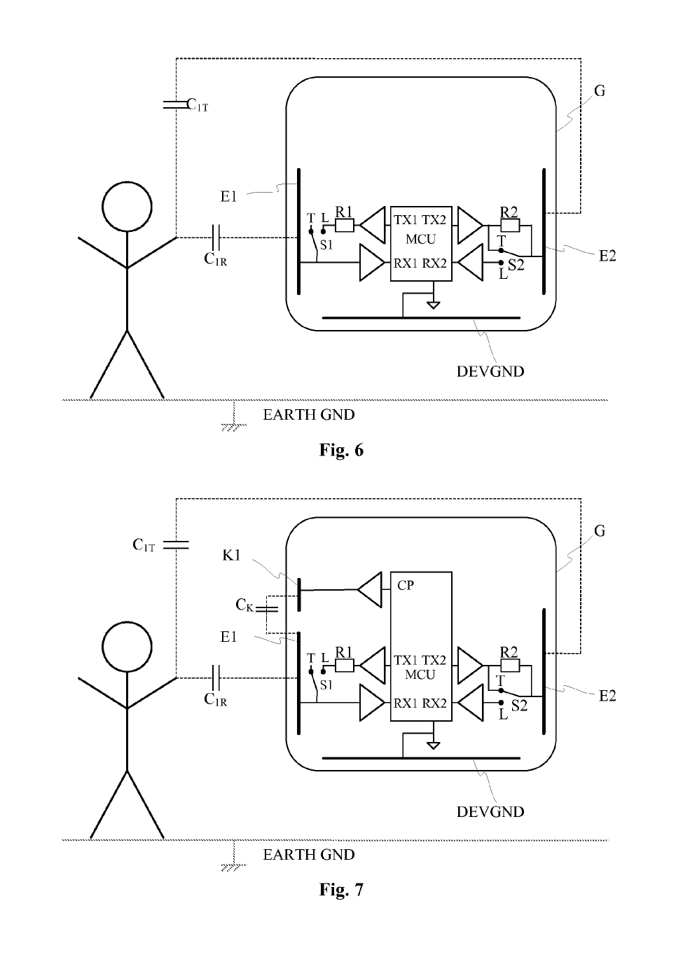

FIG. 6 shows an example of implementation of a sensor device according to various embodiments, which can be operated in a first operating mode, i.e. in a transmission mode, as well as in a second operating mode, i.e. in a loading mode.

In the switch position T, the sensor device according to various embodiments is in the transmission mode, i.e. the capacitive coupling between the electrode E2 and the electrode E1 is measured and analyzed. In the switch position L, the sensor device according to various embodiments is in the loading mode, i.e. the capacitive load at the electrode E1 (with TX1 and RX1) and the capacitive load at the electrode E2 (with TX2 and RX2) is measured and analyzed.

The sensor device can, for example, be operated cyclically in one of the two operating modes by means of the two switches S1, S2. In the loading mode, the grounding or the coupling to ground of the capacitive sensor device can be detected and analyzed. The result of the analysis can be considered for the subsequent operation of the sensor device in the transmission mode. For example, the alternating electrical signal applied to the transmitting electrode E2 can be adjusted, depending on the capacitive load of the sensors in the loading mode. However, a threshold value can also be adjusted for the analysis of a second measuring in the transmission mode.

However, the sensor device according to various embodiments can also be operated in parallel or virtually parallel in the loading mode and in the transmission mode.

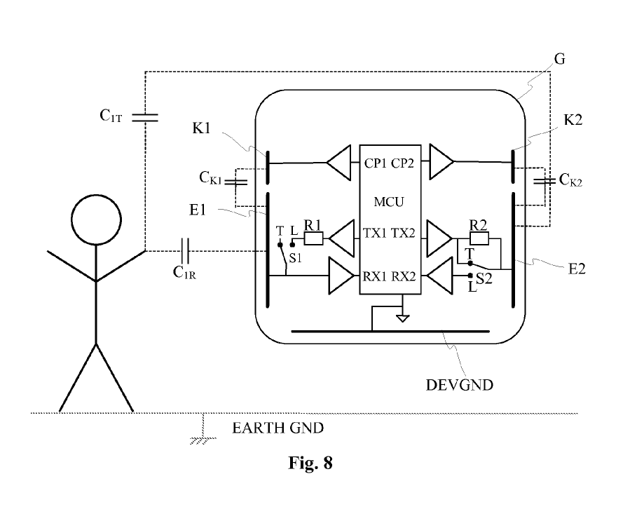

FIGS. 7 and 8 show two more examples of implementation of a sensor device according to various embodiments.

FIG. 7 provides an additional electrode K1, which is used as compensating electrode of the sensor device in the transmission mode. An alternating electrical signal is applied to the compensating electrode K1, preferentially having a phase and/or amplitude differing from the phase and/or amplitude of the alternating electrical signal applied to the electrode E1.

The compensating electrode K1 is arranged relative to the electrode E1 in such a way that the alternating electrical field emitted at the compensating electrode K1 couples into the receiving electrode E1. This way, a compensation of the capacitive environment of the hand-held device is achieved at least in the area of the receiving electrode E1.

When gripping the hand-held device with one hand, the alternating electrical field emitted at the transmitting electrode E2 in the transmission mode couples into the receiving electrode E1 via the hand. This way, the alternating electrical field emitted at the compensating electrode K1 is “bridged”. The alternating electrical field coupled into the receiving electrode E1 is used as a measure of the gripping of the hand-held device with one hand.

FIG. 8 shows the sensor device according to FIG. 7, comprising a second compensating electrode K2 in addition to the compensating electrode K1. The compensating electrode K2 is arranged relative to the transmitting electrode E2 in such a way that an alternating electrical field emitted at the compensating electrode K2 can couple into the transmitting electrode E2.

When in operation, an alternating electrical field is emitted at each of the electrodes E2, K2 and K1 when gripping the electrical hand-held device with one hand in the transmission mode (switch position T of the two switches S1 and S2), which couple into the receiving electrode E1 via the hand. The alternating electrical fields emitted at the compensating electrodes K2 and K1 enable a compensation of the capacitive environment at both sides of the housing.

Furthermore, a complete system test can be performed by means of the compensating electrodes K1 and K2. The system test can be performed prior to starting the measuring mode. The system test can also be performed at cyclical intervals in order to enable a calibration of the sensor device during operation.

The system test completely checks the microcontroller MCU, the supply lines and the electrodes. For this, the switches S1 and S2 are brought into the switch position L. An alternating electrical signal (test signal) is applied to the compensating electrode K1 and a receiving signal is tapped at the receiving electrode E1, which can be tested for compliance with pre-defined tolerances. Likewise, an alternating electrical signal (test signal) is applied to the compensating electrode K2 and a receiving signal is tapped at the electrode E2, which functions as receiving electrode in the system test. This receiving signal can also be tested for compliance with pre-defined tolerances.

According to various embodiments, also several sensor devices according to various embodiments can be provided at one hand-held device, in order to, for example, detect different positions of the hand at the hand-held device when gripping the hand-held device with the hand.

In a further development, the sensor device may comprise one transmitting electrode E2 and several receiving electrodes E1 in the transmission mode. It may also comprise several transmitting electrodes E2 and one receiving electrode E1. In a further embodiment, the sensor device may also comprise several transmitting electrodes E2 and several receiving electrodes E1 in the transmission mode. In case of several transmitting electrodes E2, a different alternating electrical signal can be applied to each transmitting electrode E2 so that different alternating electrical fields are coupled into the receiving electrode E1 via the hand, depending on the position of the gripping hand. The alternating electrical fields coupled into the receiving electrode E1 can be separated and be assigned to the respective transmitting electrode E2.

For the loading mode, the sensor device may also comprise more than two electrodes. For example, the sensor circuit LS1 of the sensor device shown in FIG. 3 may comprise additional electrodes. This also applies to the sensor circuit LS2 shown in FIG. 4.

A cell phone has been described above representative for an electrical hand-held device. A hand-held device, which can be provided with a sensor device according to various embodiments, can also be a computer mouse, a remote control for a device, a digital camera, a game controller or the like.

What is claimed is:

1. A sensor device comprising at least one first electrode and at least one second electrode being coupled with an analysis device, wherein
the at least one first electrode can be operated in a first operating mode,
the at least one second electrode can be operated in said first operating mode and in a second operating mode,
in the first operating mode, the capacitive coupling between the at least one first electrode and the at least one second electrode are analyzed by the analysis device, and
in the second operating mode, a capacitive load of the at least one second electrode against a reference ground are analyzed by the analysis device.

2. Sensor device according to claim 1, wherein the at least one first electrode can be operated in the second operating mode.

3. Sensor device according to claim 1, wherein an electrical alternating signal can be applied to the second electrode in the first operating mode and in the second operating mode, wherein the capacitive coupling between the first electrode and the second electrode is represented by the electric current flowing in the first electrode.

4. Sensor device according to claim 2, wherein an alternating electrical signal can be applied to the first electrode in the second operating mode, wherein a capacitive load of the at least one first electrode against a reference ground can be analyzed by the analysis device.

5. Sensor device according to claim 1, wherein the analysis device is configured to provide a sensor signal each in the first operating mode and in the second operating mode, which is indicative for the capacitive coupling between the first electrode and the second electrode or for the capacitive load of the first electrode and/or the second electrode, respectively.

6. Sensor device according to claim 1, wherein the sensor device can be operated sequentially in the first operating mode and in the second operating mode.

7. Sensor device according to claim 1, wherein the sensor device can be operated in parallel in the first operating mode and in the second operating mode.

8. Sensor device according to claim 1, wherein the capacitive load to be analyzed in the second operating mode can be used as reference value for adjusting a sensitivity of the sensor device in the first operating mode.

9. Sensor device according to claim 1, further comprising a third electrode, wherein an alternating electrical signal, having a phase and/or amplitude differing from the phase and/or the amplitude of the alternating electrical signal applied to the second electrode, can be applied to the third electrode.

10. Sensor device according to claim 1, further comprising a third electrode and a fourth electrode, which can each have an alternating electrical signal applied to them, wherein the third electrode can be brought into a capacitive coupling with the first electrode and the fourth electrode can be brought into a capacitive coupling with the second electrode, wherein the sensor device can be operated in a third operating mode, wherein the capacitive couplings between the first electrode and the third electrode and between the second electrode and the fourth electrode can be analyzed by the analysis device.

11. A hand-held device, comprising at least one sensor device comprising at least one first electrode and at least one second electrode being coupled with an analysis device, wherein
the at least one first electrode can be operated in a first operating mode,
the at least one second electrode can be operated in said first operating mode and in a second operating mode,
in the first operating mode, the capacitive coupling between the least one first eleectrode and the at least one second electrode are analyzed by the analysis device, and
in the second operating mode, a capacitive oad of the at least one second electrode against a reference ground are analyzed by the analysis dedvice.

12. Hand-held device according to claim 11, wherein the first electrode and the second electrode are arranged relative to one another on the hand-held device in such a way that they are at least partially overlapped by a hand when gripping the hand-held device with one hand.

13. Hand-held device according to claim 12, wherein the first electrode and the second electrode are arranged at two walls facing each other, or at two side walls of a housing of the hand-held device facing each other.

14. Hand-held device according to claim 11, wherein the handheld device comprises at least one of a computer mouse, remote control for device, digital camera and game controller.

15. A method for the detection of the gripping of a hand-held device with a first electrode and a second electrode being coupled with an analysis device, with one hand, comprising at least the following steps:
applying an alternating electrical signal to the seconed electrode, so that it emits an alternating electrical field,
in a first operating mode, measuring the capacitive coupling between the first electrode and the second electrode and providing a first measuring signal,
in a second operating mode, measuring the capacitive load of the second electrode against a reference ground and providing a second measuring signal,
wherein the measuring signals are indicative for the gripping of the hand-held device with the hand.

16. Method according to claim 15, wherein an alternating electrical signal is applied to the first electrode in the second operating mode, so that it emits an alternating electrical field and the capacitive load of the first electrode is measured.

17. Method according to claim 15, with the amplitude of the alternating electrical signal applied to the second electrode in the first operating mode being adjusted, depending on the capacitive load of the electrodes in the second operating mode.

18. Method according to claim 15, with measuring steps being performed in parallel or sequentially.

19. Method according to claim 15, with the second measuring signal being used to adjust the sensitivity of the sensor device in the first operating mode.

20. Method according to claim 15, wherein an alternating electrical signal is applied to one first compensating electrode in the first operating mode.

21. Method according to claim 20, wherein the alternating electrical signal applied to the first compensating electrode has a phase and/or amplitude differing from the phase and/or amplitude of the alternating electrical signal applied to the first electrode.

22. Method according to claim 15, wherein an alternating electrical signal is applied to each of the one first compensating electrode and the one second compensating electrode, so that the first compensating electrode can be brought into a capacitive coupling with the first electrode and the second compensating electrode can be brought into a capacitive coupling with the second electrode, wherein the sensor device is operated in a third operating mode, wherein the capacitive couplings between the first electrode and the first compensating electrode and between the second electrode and the second com-pensating electrode are analyzed by the analysis device.
